(19) United States
(12) Patent Application Publication
(10) Pub. No.: US 2026/0365525 A1
(43) Pub. Date: Nov. 19, 2026

(54) Silicon Carbide Powder and Method for Producing Same

(71) Applicant: Tokuyama Corporation, Yamaguchi (JP)

(72) Inventors: Hiroshi Furuya, Yamaguchi (JP); Kentaro Matsuo, Yamaguchi (JP)

(73) Assignee: Tokuyama Corporation, Yamaguchi (JP)

(21) Appl. No.: 19/132,434

(22) PCT Filed: Oct. 5, 2023
(86) PCT No.: PCT/JP2023/036398

§ 371 Date: May 23, 2025

(30) Foreign Application Priority Data
Dec. 9, 2022 (JP) 2022-197053

(51) Int. Cl. C01B 32/984

(52) U.S. Cl. CPC C01B 32/984; C01P 2006/11

(57) ABSTRACT

A method for producing a silicon carbide powder by mixing a metal silicon powder and a carbon powder and performing self-propagating high-temperature synthesis includes a mixing step of mixing the metal silicon powder and the carbon powder to obtain a raw material for producing silicon carbide; and a production step of subjecting the metal silicon powder and carbon powder after mixing to self-propagating high-temperature synthesis in an inert gas atmosphere to obtain a silicon carbide powder, in which a bulk density of the metal silicon powder and carbon powder after mixing in the mixing step is twice or more a bulk density of the metal silicon powder and carbon powder before the mixing step.

### TECHNICAL FIELD

The present invention relates to a method for producing a silicon carbide powder and a silicon carbide powder. Specifically, the present invention relates to a method for producing a silicon carbide powder having a reduced content of carbon and a reduced content of metal impurities that can be used as a raw material for a semiconductor wafer, and a silicon carbide powder.

### BACKGROUND ART

Silicon carbide (SiC) has excellent properties such as high hardness, high strength, high heat resistance, and high thermal conductivity, and thus has been used as an abrasive, a refractory, a heating element, and the like. In recent years, a demand for SiC as a raw material for a SiC semiconductor wafer has also increased. A silicon carbide powder suitable for these applications has been produced, and particularly a high-purity silicon carbide powder is required for the raw material for a SiC semiconductor wafer and a raw material of a SiC sintered body for a semiconductor production application or the like. It is known that a cause of a decrease in purity of the silicon carbide powder is unreacted silicon and carbon derived from a raw material for the production, and when a silicon carbide powder containing the unreacted silicon and carbon is used as a raw material, a product is adversely influenced. For example, Patent Literature 1 discloses that when unreacted carbon (free carbon) is contained in a raw material silicon carbide powder for producing a SiC single crystal by a sublimation recrystallization method, the unreacted carbon is incorporated into the SiC single crystal to cause defect generation. In addition, Patent Literature 2 discloses that when free silicon is contained in a raw material silicon carbide powder for producing a silicon carbide sintered body, sintering is inhibited or defects are generated in the sintered body.

Known methods for producing silicon carbide include: (1) an Acheson method in which silica sand and coke are heated at a higher temperature by electrical heating (for example, Patent Literatures 1 and 3); (2) a method in which a mixture containing silica and carbon powder is externally heated to be reduced and subjected to a carbonization reaction (for example, Patent Literature 4); (3) a method in which a mixture containing a metal silicon powder and a carbon powder is externally heated to be carbonized (for example, Patent Literature 5); and (4) a method in which a mixture containing a metal silicon powder and a carbon powder is preheated and then a part of the mixture is ignited and combusted (also called a self-propagating high-temperature synthesis method or a combustion synthesis method, for example, Patent Literature 6).

The method (1) is the most common method for producing a silicon carbide powder, and the silicon carbide powder can be produced relatively inexpensively using large-scale equipment; however, since there is temperature variation in a furnace, free silicon and free carbon are likely to be generated, making it difficult to obtain a high-purity product. In the production method (2), by using high-purity silica and the carbon powder as a raw material, a silicon carbide powder having a relatively high purity is easily obtained, but silica is used as a raw material, and free SiO₂ tends to be generated. In the production method (3), by using a high-purity metal silicon powder and the carbon powder as a raw material, a silicon carbide powder having a relatively high purity is easily obtained, but silicon is volatilized during high-temperature firing, and an amount of free carbon cannot be highly reduced. In the production method (4), synthesis can be performed at a lower temperature than in the production method (3), and therefore volatilization of silicon can be prevented; however, since a reaction temperature is low, a conversion rate to silicon carbide is reduced, resulting in a large amount of free silicon and free carbon. Free carbon can be removed relatively easily by performing a heat treatment in an air atmosphere, and silicon-based impurities require a treatment using hydrofluoric acid or the like. When the content of free carbon is high, the corresponding content of the silicon-based impurities also increases, and thus reducing the content of free carbon after the reaction is extremely important for improving the purity of the silicon carbide powder.

### CITATION LIST

### Patent Literature

Patent Literature 1: Japanese Patent Laid-Open No. 2019-151533
Patent Literature 2: Japanese Patent Laid-Open No. S63-17258
Patent Literature 3: Japanese Patent Laid-Open No. 2015-157737
Patent Literature 4: Japanese Patent Laid-Open No. 2012-246165
Patent Literature 5: WO2012-157293
Patent Literature 6: Japanese Patent Laid-Open No. S53-25300

### SUMMARY OF INVENTION

### Technical Problem

The method (1) is the most common method for producing a silicon carbide powder, and has an advantage of being able to use large-scale equipment to produce the silicon carbide powder relatively inexpensively; however, there is room for improvement in that there is temperature variation in a furnace, and thus free silicon and free carbon are likely to be generated, making it difficult to obtain a high-purity product. In the production method (2), by using high-purity silica and the carbon powder as a raw material, a silicon carbide powder having a relatively high purity is easily obtained, but silica is used as a raw material, and free SiO₂ tends to be generated. In the production method (3), by using a high-purity metal silicon powder and the carbon powder as a raw material, a silicon carbide powder having a relatively high purity is easily obtained, but Si is volatilized during high-temperature firing, and the amount of free carbon cannot be highly reduced. In the production method (4), synthesis can be performed at a lower temperature than in the production method (3), and therefore volatilization of Si can be prevented; however, since a reaction temperature is low, a conversion rate to silicon carbide is reduced, resulting in a large amount of free silicon and free carbon.

In addition, for example, as described in Patent Literatures 1 and 4, it has been attempted to improve the purity by removing impurities from the produced silicon carbide powder, but there is a limit to improvement of the purity.

As described above, there is a demand for a silicon carbide powder containing small amounts of Si-based impurities, such as free silicon and free SiO₂, and free carbon, but the silicon carbide powder in which both amounts of the Si-based impurities and free carbon are highly reduced has not been obtained so far. Therefore, an object of the present invention is to provide a silicon carbide powder in which both amounts of silicon-based impurities and free carbon are highly reduced.

### Solution to Problem

The present inventors have conducted extensive research to solve the above problem. As a result of investigating a factor that causes generation of free silicon and free carbon in the self-propagating high-temperature synthesis method, which is the above method (4), it has been found that free silicon and free carbon tend to be generated when there is unevenness in mixing of raw materials thereof. Therefore, based on this finding, the inventors have conducted extensive research into a method for preparing a mixed powder containing a metal silicon powder and a carbon powder to be subjected to a self-propagating high-temperature synthesis method. As a result, the inventors have found that when mixing the metal silicon powder and the carbon powder to obtain a mixed powder, by setting a bulk density after mixing to be within a predetermined range relative to a bulk density before mixing, a mixed powder with little mixing unevenness can be obtained, and that by producing a silicon carbide powder using the mixed powder, the contents of free silicon and free carbon can be reduced, and the content of metal impurities can also be reduced, which has led to completion of the present invention.

That is, a first aspect of the present invention provides a method for producing a silicon carbide powder by mixing a metal silicon powder and a carbon powder and performing self-propagating high-temperature synthesis, and the method includes: a mixing step of mixing the metal silicon powder and the carbon powder to obtain a raw material for producing silicon carbide; and a production step of subjecting the metal silicon powder and carbon powder after mixing to self-propagating high-temperature synthesis in an inert gas atmosphere to obtain a silicon carbide powder, in which a bulk density of the metal silicon powder and carbon powder after mixing in the mixing step is twice or more a bulk density of the metal silicon powder and carbon powder before the mixing step.

In the above first aspect of the present invention, the following aspects can be suitably adopted.

(1) The production step is performed in an electric furnace.

(2) A temperature in the electric furnace is 900 °C to 2050 °C.

(3) In the mixing step, at least one mixing means selected from the group consisting of a ball mill, a planetary ball mill, a jet mill, and a vibration mill is used.

(4) A metal silicon powder having an average particle diameter of 20 μm or less and a carbon powder having a primary particle diameter of 100 nm or less are mixed.

(5) A heat treatment step of subjecting the silicon carbide powder obtained in the production step to a heat treatment in an oxidizing atmosphere is included.

(6) In the heat treatment step, a heat treatment temperature is 600 °C to 1200 °C.

In addition, the second aspect of the present invention provides a silicon carbide powder having a content of free carbon of 0.001 mass % to 0.5 mass % and a content of free metal silicon of 0.01 mass % to 1.0 mass %.

In the above second aspect of the present invention, the following aspects can be suitably adopted.

(7) A total content of metal impurities of B, Al, Fe, Cu, Mg, Ni, and Ca is 1 ppm or less.

(8) A content of free carbon is 0.001 mass % to 0.5 mass %, a content of free metal silicon is 0.01 mass % to 1.0 mass %, and a total content of metal impurities of B, Al, Fe, Cu, Mg, Ni, and Ca is 1 ppm or less.

### Advantageous Effects of Invention

According to the present invention, a high-purity silicon carbide powder having a low content of unreacted carbon can be obtained. As a result, when the high-purity silicon carbide powder is used as a raw material for a SiC single crystal produced by a sublimation recrystallization method, a single crystal with few defects can be produced. In addition, when the high-purity silicon carbide powder is used as a raw material for a sintered body, a sintered body having good sinterability and few defects can be produced. Further, the silicon carbide powder obtained by the production method according to the present invention has a low content of metal impurities and can be suitably used as a raw material for a SiC semiconductor wafer.

### DESCRIPTION OF EMBODIMENTS

The present invention is characterized in that, when a silicon carbide powder is produced by mixing a metal silicon powder and a carbon powder and performing self-propagating high-temperature synthesis, a bulk density of the metal silicon powder and carbon powder after mixing is twice or more a bulk density of the metal silicon powder and carbon powder before mixing. With the production method according to the present invention, a high-purity silicon carbide powder having low contents of unreacted free silicon and free carbon and metal impurities can be obtained. The details of a reason why the high-purity silicon carbide powder can be obtained with the production method according to the present invention are unclear, and the present inventors have the following presumption. That is, as described above, in a self-propagating high-temperature synthesis method, since a reaction temperature is low, a conversion rate to silicon carbide is reduced, and the amounts of free silicon and free carbon tend to increase. This tendency is particularly likely to occur when the metal silicon powder and the carbon powder are mixed insufficiently before a reaction. The carbon powder often forms an aggregate, and it tends to be difficult to sufficiently mix the carbon powder with the metal silicon powder simply by adding the carbon powder to the metal silicon powder. In the self-propagating high-temperature synthesis method, a silicon powder and a carbon powder are mixed together and then subjected to a reaction. However, when the mixing is insufficient, a bulky aggregate of the carbon powder is not sufficiently crushed, and a bulk density of the mixed powder does not change remarkably. To the contrary, by sufficiently mixing the silicon powder and the carbon powder using mixing means such as a ball mill, the carbon powder that forms an aggregate is crushed and the silicon powder and the carbon powder are sufficiently mixed, whereby the bulk density of the above mixed powder after mixing increases. Therefore, it is presumed that the silicon powder and the carbon powder can be uniformly mixed by increasing the bulk density of the mixed powder to a predetermined ratio or more relative to the bulk density before mixing. It is presumed that by subjecting the uniformly mixed powder to production, the high-purity silicon carbide powder having low contents of unreacted carbon and metal impurity can be obtained.

In the present description, unless otherwise specified, a notation “A to B” regarding numerical values A and B means “A or more and B or less”. In the notation, when a unit is added to only the numerical value B, the unit is also applied to the numerical value A. Hereinafter, a method for producing a silicon carbide powder according to the present invention will be described in detail.

### <Method for Producing Silicon Carbide Powder>

### [Metal Silicon Powder]

In the production method according to the present invention, a mixing step of mixing a metal silicon powder and a carbon powder to obtain a mixed powder (hereinafter also referred to as a “raw material for producing silicon carbide”) is performed. From a viewpoint of a reaction yield and a viewpoint of reducing contents of the unreacted metal silicon powder and carbon powder, a Si/C mixing ratio in the raw material for producing silicon carbide is preferably such that a Si/C molar ratio is 0.98 or more and 1.02 or less.

From a viewpoint of reactivity, the metal silicon powder preferably has a particle diameter of 2.0 μm to 50.0 μm, and more preferably 4.0 μm to 35.0 μm. The metal silicon powder has an average particle diameter of preferably 20 μm or less, and more preferably 2.0 μm to 10.0 μm. When the particle diameter of the metal silicon powder is too small, a ratio of a surface oxide film increases, and thus amounts of Si-based impurities and free carbon in the silicon carbide powder tend to increase. In addition, when the particle diameter is too large, the metal silicon powder is difficult to uniformly mix with the carbon powder, the reaction rate is not sufficiently high, and the amounts of Si-based impurities and free carbon tend to increase. When the metal silicon powder contains metal impurities, a concentration of the metal impurities in the silicon carbide powder also tends to be high, so that a total content of metal impurities of B, Al, Fe, Cu, Mg, Ni, and Ca in the metal silicon powder is preferably 1 ppm or less, and more preferably 0.1 ppm or less.

### [Carbon Powder]

In the production method according to the present invention, the carbon powder preferably has a primary particle diameter of 100 nm or less, and more preferably 10 nm or more and 100 nm or less. When the particle diameter of the carbon powder is too small, the carbon powder is likely to adsorb air and moisture, and a purity of the silicon carbide powder tends to decrease. When the particle diameter is too large, the carbon powder is difficult to uniformly mix with the metal silicon powder, the reaction rate is not sufficiently high, and the amounts of Si-based impurities and free carbon tend to increase. When the carbon powder contains metal impurities, the concentration of the metal impurities in the silicon carbide powder also tends to be high, so that a concentration of the metal impurities in the carbon powder is preferably 50 ppm or less, more preferably 10 ppm or less, and still more preferably 1 ppm or less. A type of the carbon powder is not particularly limited, and for example, carbon black, graphite, activated carbon, or the like can be used. Carbon black produced by using various methods such as a furnace method (furnace black), a channel method (channel black), and an acetylene method (acetylene black) can be used.

### [Raw Material for Producing Silicon Carbide]

When the above silicon powder and carbon powder are mixed to obtain the raw material for producing silicon carbide, it is particularly preferred to use a metal silicon powder having an average particle diameter of 20 μm or less and a carbon powder having a primary particle diameter of 100 nm or less.

### [Other Raw Materials]

To the above raw material for producing silicon carbide, in addition to the metal silicon powder and the carbon powder, a silicon carbide powder may be added as a diluent for a purpose of controlling a reaction temperature or the like, as long as an effect of the present invention is not impaired. In the case of using the silicon carbide powder as the diluent, the Si/C molar ratio in the mixed powder is adjusted including the diluent silicon carbide powder. A blending amount of the silicon carbide powder is generally 50 mass % or less of the mixed powder. When the silicon carbide powder as the diluent contains a large amount of metal impurities, the amount of the metal impurities in the produced silicon carbide powder is also large, and thus the silicon carbide powder has a content of metal impurities of preferably 200 ppm or less, more preferably 100 ppm or less, and still more preferably 50 ppm or less. The silicon carbide powder produced by the production method according to the present invention may be used as the silicon carbide powder for the diluent.

### [Mixing Step]

In the production method according to the present invention, in the method of mixing the metal silicon powder and the carbon powder to obtain the raw material for producing silicon carbide, the bulk density of the raw material for producing silicon carbide after mixing needs to be twice or more the bulk density of the metal silicon powder and carbon powder before mixing. As described above, since the carbon powder is aggregated, by crushing the aggregate while mixing the carbon powder with the silicon powder, it is possible to perform uniform mixing. The bulk density of the raw material for producing silicon carbide after mixing can be measured by filling a glass vessel having an internal volume of 100 cc with the raw material for producing silicon carbide after mixing and measuring a weight. The filling is performed loosely without tapping or applying a pressure. The bulk density before mixing is defined by calculating a bulk density of each of the metal silicon powder and the carbon powder in the same manner as above, and then calculating a weighted average of the bulk densities of the powders according to a mixing ratio. The bulk density of the metal silicon powder and carbon powder after mixing in the production method according to the present invention is sufficiently twice or more the bulk density of the metal silicon powder and carbon powder before mixing, and is preferably in the range of twice or more and 10 times or less, and particularly preferably in the range of twice or more and 8 times or less.

As the method of mixing the metal silicon powder and the carbon powder in the production method according to the present invention, specifically, preferred methods include mixing means using a blender, a mixer, or a ball mill. Specifically, more preferred is a method in which a raw material is subjected to a load during mixing, particularly as with a ball mill, since homogeneity of the metal silicon powder and the carbon powder increases. For example, in the case of selecting mixing using a ball mill, a material of a vessel to be filled with the metal silicon powder and the carbon powder, a ball, or the like is preferably a material that is not easily mixed into the raw material due to abrasion during the mixing, and is more preferably high-purity silicon carbide. A diameter of the ball may be selected such that the metal silicon powder and the carbon powder are mixed homogeneously, and the diameter is preferably 3 mm to 20 mm. A rotation speed can be any rotation speed, and is preferably 50 rpm to 500 rpm. In addition, in the case of a method in which a raw material is subjected to a load during mixing, as a ball mill, when mixing is performed in the presence of oxygen, there is a concern that a fresh surface of metal silicon is oxidized to increase the amounts of Si-based impurities and free carbon in the silicon carbide powder, and therefore, it is preferable to prevent oxidation by performing mixing in a non-oxidizing atmosphere (in particular, in a rare gas atmosphere such as argon) and taking out the mixture after cooling the mixture to room temperature.

### [Production Step]

In the production method according to the present invention, a production step of subjecting the raw material for producing silicon carbide to self-propagating high-temperature synthesis to obtain the silicon carbide powder is performed. The apparatus is not particularly limited as long as the self-propagating high-temperature synthesis can be performed, and it is preferable to produce the silicon carbide powder by the self-propagating high-temperature synthesis by filling an electric furnace with the raw material for producing silicon carbide, heating the electric furnace, and, if necessary, igniting a part of the raw material for producing silicon carbide.

In the case of producing the silicon carbide powder by using the above method, when oxygen is present in the electric furnace, a by-product such as silicon oxide is generated due to a side reaction. When nitrogen is present in the electric furnace, a content of nitrogen in the produced silicon carbide increases. Therefore, the production step is preferably performed under an inert atmosphere or under a reduced pressure. The inert atmosphere can be, for example, a rare gas such as helium, neon, or argon. A pressure in performing the production step under the inert atmosphere is not particularly limited, and the production step can be performed under an atmospheric pressure or under a pressurized atmosphere. In order to remove oxygen, nitrogen, moisture, and the like in the electric furnace after placing the raw material in the electric furnace, it is preferable to perform a step of reducing the pressure in the electric furnace to 0.5 Pa or more and 10 Pa or less, then introducing an inert gas, and restoring the pressure to a predetermined pressure at least once before raising the temperature in the electric furnace. After replacing the inside of the reaction vessel with the inert gas, the pressure in the reaction vessel may be reduced again to 0.5 Pa or more and 10 Pa or less, and heated to a temperature lower than a production temperature to bake the raw material for producing silicon carbide.

For a heating temperature in the electric furnace, from a viewpoint of reliably performing a production reaction for silicon carbide, the temperature in the electric furnace is preferably 900 °C to 2050 °C, more preferably 1000 °C to 1800 °C, and particularly preferably 1200 °C to 1500 °C.

A heating method is not particularly limited, and for example, the mixed powder filled in a heat-resistant reaction vessel made of ceramics, graphite, or the like may be placed in the electric furnace, and after adjusting the atmosphere, the temperature in the electric furnace may be raised from room temperature to the production temperature. A temperature raising time is not particularly limited, and since the temperature is likely to be uniformly raised, the temperature is preferably raised over 1 hour or longer. An upper limit of the temperature raising time is not particularly limited, and is preferably 1 to 24 hours from a viewpoint of efficient production. After the temperature is raised to the production temperature, a self-propagating high-temperature synthesis reaction may be initiated immediately after ignition, or the production step may be initiated by ignition after the temperature is maintained at the production temperature for a while. In the case of initiating the self-propagating high-temperature synthesis reaction by ignition after the temperature is maintained at the production temperature for a while, the maintaining time at the heating temperature is preferably within 24 hours from the viewpoint of the efficient production. Further, the production temperature may be set high and the self-propagating high-temperature synthesis reaction may be initiated by spontaneous ignition.

### [Heat Treatment Step]

In the production method according to the present invention, a heat treatment step of subjecting the silicon carbide powder obtained in the production step to a heat treatment in an oxidizing atmosphere may be performed if necessary. Although the silicon powder and the carbon powder in the raw material for producing silicon carbide are almost consumed by the above production step, some unreacted silicon powder and carbon powder may remain. Therefore, by subjecting the silicon carbide powder after the production step to a heat treatment in an oxidizing atmosphere, the remaining carbon is oxidized and converted into carbon monoxide or carbon dioxide, thereby consuming some of the unreacted carbon powder. In the production method according to the present invention, the heat treatment step may be performed consecutively after the production step, or another heating furnace may be filled with the silicon carbide powder obtained after the production step and a heat treatment may be performed.

In the heat treatment step, the oxidizing atmosphere may be, for example, air and an oxidizing gas such as oxygen. The pressure is not particularly limited, and is preferably an atmospheric pressure. Air may flow through the heating furnace using a blower, a fan, or the like.

The temperature in the heat treatment step is preferably 600 °C to 1200 °C, more preferably 600 °C to 1000 °C, and particularly preferably 700 °C to 900 °C. When the heating temperature is lower than the above range, the oxidation of the remaining carbon does not proceed sufficiently, whereas when the heating temperature is higher than the above range, the oxidation of the silicon carbide proceeds remarkably.

A heating time is not particularly limited, the heating may be maintained until the carbon powder in the silicon carbide powder obtained in the production step reacts and is completely consumed, and the heating time may be, for example, 1 to 10 hours.

### [Pulverization Step]

In the production method according to the present invention, pulverization may be performed after the heat treatment step, if necessary, to adjust the particle diameter. The pulverization method is not particularly limited, and for example, pulverization using a vibrating ball mill, a rotating ball mill, or a jet mill can be exemplified as a preferred method. A material of a vessel, a ball, and the like is preferably a material that is not easily mixed into the raw material due to abrasion, and is more preferably high-purity silicon carbide. Even when impurities are mixed, the impurities can be removed in a cleaning step to be described later.

### [Cleaning Step]

In the production method according to the present invention, a cleaning treatment may be performed in order to reduce the amount of the metal impurities and the like, if necessary. An acid aqueous solution or an alkali aqueous solution can be used for cleaning, and the solution is suitably selected according to an element to be reduced in amount. Examples of the acid aqueous solution include hydrochloric acid, hydrofluoric acid, nitric acid, sulfuric acid, and phosphoric acid, and examples of the alkali aqueous solution include a sodium hydroxide aqueous solution and a potassium hydroxide aqueous solution. If necessary, the cleaning solution may be heated to promote dissolution.

### <Silicon Carbide Powder>

With the production method according to the present invention, a high-purity silicon carbide powder having low contents of free carbon and metal silicon can be obtained. Specifically, a silicon carbide powder having a content of free carbon of 0.5 mass % or less and a content of free metal silicon of 1.0 mass % or less, and preferably having a content of free carbon of 0.001 mass % to 0.5 mass % and a content of free metal silicon of 0.01 mass % to 1.0 mass % can be obtained. The silicon carbide powder according to the present invention has an extremely low content of carbon and can be particularly suitable for a semiconductor application that requires a high purity. The content of free carbon can be calculated by performing the heat treatment step and calculating a weight loss before and after the heat treatment step. By performing the heat treatment step after the above production step, a silicon carbide powder having a content of carbon of 0.05 mass % or less and preferably 0.001 mass % to 0.05 mass % can be obtained.

Further, with the production method according to the present invention, a high-purity silicon carbide powder having a total content of metal impurities of B, Al, Fe, Cu, Mg, Ni, and Ca of 1 ppm or less can be obtained. The content of the metal impurities can be measured by glow discharge mass spectrometry.

### <Application of Silicon Carbide Powder>

An application of the silicon carbide powder according to the present invention is not particularly limited. The silicon carbide powder has low contents of Si-based impurities and free carbon, and can thus be particularly suitably used as a raw material for a SiC single crystal produced by a sublimation recrystallization method or a raw material for a SiC sintered body for production of a semiconductor or the like, which particularly requires a high-purity silicon carbide powder.

### EXAMPLES

The present invention will be described in more detail below, but the present invention is not limited to these Examples. Various physical properties in Examples and Comparative Examples were measured by the following methods.

### (1) Concentration of Free Carbon

The concentration of free carbon was calculated based on the weight loss in the heat treatment step. Specifically, the following steps were performed. Approximately 10 g of the silicon carbide powder produced by the production method according to the present invention was charged into an alumina-silica porcelain vessel having a volume of 28 cc whose weight had been measured in advance, and the weight was measured. The porcelain vessel was placed in an electric furnace, then the temperature was raised to 800 °C in an air atmosphere under a normal pressure, and after reaching 800 °C, the temperature was held for 2 hours. Thereafter, the weight after cooling to room temperature was measured, and the weight loss after the heat treatment step was divided by the weight of the silicon carbide powder subjected to the heat treatment step to calculate the concentration of free carbon.

### (2) Concentration of Free Silicon

The concentration of free silicon was calculated based on an integrated intensity ratio of a (111) peak of 3C type silicon carbide to a (111) peak of metal silicon in 20 measurement of X-ray diffraction. Five samples were prepared by adding 0.1 mass % to 5.0 mass % of metal silicon to a silicon carbide powder in advance, and X-ray diffraction measurement (SmartLab manufactured by Rigaku Holdings Corporation) was performed to obtain a calibration curve of the integrated intensity ratio of the (111) peak of 3C type silicon carbide to the (111) peak of metal silicon in the 20 measurement of the X-ray diffraction with respect to a content of metal silicon. The concentration of free silicon in the silicon carbide powder was calculated by applying, to the calibration curve, the integrated intensity ratio of the (111) peak of 3C type silicon carbide to the (111) peak of metal silicon in the 20 measurement of the X-ray diffraction of the produced silicon carbide powder.

### (3) Amount of Metal Impurities

As for the amount of metal impurities, a total amount of alkali metals, alkaline earth metals, and transition metals with atomic numbers 3 to 92 was measured by glow discharge mass spectrometry (ELEMENT GD PLUS, manufactured by ThermoFishier Scientific).

### (4) Bulk Density

The bulk density after mixing a metal silicon powder and a carbon powder was calculated by filling a measuring cylinder having a volume of 100 cc with the mixed powder up to a 100 cc mark and taking the measured weight as a weight per 100 cc. When filling the measuring cylinder with the mixed powder, the mixed powder was charged into the measuring cylinder placed on an electronic balance using a medicine spoon, and the mixed powder was made in a loosely packed state without being applied with a special pressure.

In addition, the bulk density before mixing was determined by calculating a bulk density of each of the metal silicon powder and the carbon powder in the same manner as in the method for measuring the bulk density of the mixed powder, and then calculating a weighted average of the bulk densities of the powders according to the mixing ratio.

### (5) Particle Diameter and Average Particle Diameter of Metal Silicon Powder and Primary Particle Diameter of Carbon Powder

The particle diameter and the average particle diameter of the metal silicon powder were measured using a laser diffraction/scattering type particle diameter measuring device (Partica LA-950V2 manufactured by Horiba, Ltd.). Ethanol was used as a dispersion medium. A median diameter (D50) obtained by measurement was defined as the average particle diameter.

The primary particle diameter of the carbon powder was calculated by measuring a length of arbitrary selected particle from an observation image at a magnification of 100,000 times obtained using a scanning electron microscope (FE-SEM JSM-7800 Prime manufactured by JEOL Ltd.).

### Example 1

A metal silicon powder having an average particle diameter of 5.0 μm and a total content of metal impurities of B, Al, Fe, Cu, Mg, Ni, and Ca of 0.51 ppm and acetylene black having a particle diameter of 30 nm, as a carbon powder, were weighed at a molar ratio of 1.00:1.00 (Si/C molar ratio: 1.00) and charged into a ball mill pot. A bulk density before mixing was 0.08 g/cm³. The two powders were mixed for 30 minutes at a rotation speed of 125 rpm using a ball mill to obtain a raw material for producing silicon carbide having a bulk density of 0.35 g/cm³ (the bulk density after mixing was 4.28 times the bulk density before mixing). An atmosphere during mixing was argon, and the atmosphere was substituted with air after cooling. A material of a mill ball was silicon carbide.

A graphite crucible was filled with the mixed powder and was then placed in an electric furnace. An operation of reducing a pressure in the furnace to 0.5 Pa or more and 10 Pa or less, introducing argon having a purity of 99.999%, and then restoring the pressure to a normal pressure was repeated twice. While maintaining the atmospheric pressure, argon flows through the electric furnace at a flow rate of 5 L/min, and the temperature was raised from room temperature to 1200 °C over 3 hours. During the temperature raising, spontaneous ignition causes self-propagating high-temperature synthesis to obtain a silicon carbide powder. In the resulting silicon carbide, free carbon was 0.01 mass % and free silicon was 0.1 mass % or less. Evaluation results for the obtained silicon carbide powder are shown in Table 1.

### Example 2

A silicon carbide powder was synthesized in the same manner as in Example 1 except that a mixing time in a ball mill was 60 minutes. A bulk density of a raw material for producing silicon carbide after mixing was 0.48 g/cm³ (the bulk density after mixing was 5.93 times the bulk density before mixing). In the obtained silicon carbide, free carbon was 0.01 mass % and free silicon was 0.1 mass % or less. Evaluation results for the obtained silicon carbide powder are shown in Table 1.

### Example 3

A silicon carbide powder was synthesized in the same manner as in Example 1 except that a mixing time in a ball mill was 10 minutes. A bulk density of a raw material for producing silicon carbide after mixing was 0.17 g/cm³ (the bulk density after mixing was 2.11 times the bulk density before mixing). In the obtained silicon carbide, free carbon was 0.31 mass % and free silicon was 0.7 mass %. Evaluation results for the obtained silicon carbide powder are shown in Table 1.

### Example 4

An alumina-silica porcelain vessel was filled with a silicon carbide powder prepared in the same manner as in Example 1 and was then placed in an electric furnace. The furnace was heated to 800 °C over 1 hour while maintaining the air atmosphere and the normal pressure, and after reaching 800 °C, the temperature was maintained for 2 hours. After maintaining the temperature for 2 hours, the furnace was cooled to room temperature to obtain a silicon carbide powder. In the obtained silicon carbide, free carbon was 0.01 mass % and free silicon was 0.1 mass % or less. Evaluation results for the obtained silicon carbide powder are shown in Table 1.

### Comparative Example 1

A silicon carbide powder was synthesized in the same manner as in Example 1 except that a mixing time in a ball mill was 5 minutes. A bulk density of a raw material for producing silicon carbide after mixing was 0.12 g/cm³ (the bulk density after mixing was 1.44 times the bulk density before mixing). In the obtained silicon carbide, free carbon was 1.09 mass % and free silicon was 2.5 mass %. Evaluation results for the obtained silicon carbide powder are shown in Table 1.

### Comparative Example 2

The metal silicon powder and acetylene black having a particle diameter of 30 nm, as a carbon powder, were weighed at a molar ratio of 1.00:1.00 (Si/C molar ratio: 1.00) and charged into a polyethylene bag with a zipper. A silicon carbide powder was synthesized in the same manner as in Example 1, except that the polyethylene bag was shaken up and down for 5 minutes to mix the metal silicon powder and the carbon powder to obtain a raw material for producing silicon carbide. A bulk density of a raw material for producing silicon carbide after mixing was 0.08 g/cm³ (the bulk density after mixing was 1.02 times the bulk density before mixing). In the obtained silicon carbide, free carbon was 1.79 mass % and free silicon was 4.2 mass %. Evaluation results for the obtained silicon carbide powder are shown in Table 1.

### Comparative Example 3

An alumina-silica porcelain vessel was filled with a silicon carbide powder prepared in the same manner as in Comparative Example 1 and was then placed in an electric furnace. The furnace was heated to 800 °C over 1 hour while maintaining the air atmosphere and the normal pressure, and after reaching 800 °C, the temperature was maintained for 2 hours. After maintaining the temperature for 2 hours, the furnace was cooled to room temperature to obtain a silicon carbide powder. In the obtained silicon carbide, free carbon was 0.01 mass % and free silicon was 2.5 mass %. Evaluation results of the obtained silicon carbide powders are shown in Table 1.

TABLE 1

| | | | Bulk | | | |
|---|---|---|---|---|---|---|
| | | | density | | | |
| | | Bulk | ratio of | | | |
| | | density of | before | | | Amount |
| | Mixing | mixed raw | mixing to | Concentration | Concentration | of metal |
| | time | materials | after | of free carbon | of free silicon | impurities |
| | minute | g/cm³ | mixing | mass % | mass % | ppm |
| Example 1 | 30 | 0.35 | 4.28 | 0.01 | <0.1 | 0.5 |
| Example 2 | 60 | 0.48 | 5.93 | 0.01 | <0.1 | 0.6 |
| Example 3 | 10 | 0.17 | 2.11 | 0.31 | 0.7 | 0.5 |
| Example 4 | 30 | 0.35 | 4.28 | 0.01 | <0.1 | 0.5 |
| Comparative | 5 | 0.12 | 1.44 | 1.09 | 2.5 | 1.5 |
| Example 1 | | | | | | |
| Comparative | 5 | 0.08 | 1.02 | 1.79 | 4.2 | 2.2 |
| Example 2 | | | | | | |
| Comparative | 5 | 0.12 | 1.44 | 0.01 | 2.5 | 1.5 |
| Example 3 | | | | | | |

1. A method for producing a silicon carbide powder by mixing a metal silicon powder and a carbon powder and performing self-propagating high-temperature synthesis, the method comprising:
mixing a metal silicon powder having an average particle diameter of 20 μm or less and a carbon powder having a primary particle diameter of 100 nm or less to obtain a raw material for producing silicon carbide; and
subjecting the metal silicon powder and carbon powder after mixing to self-propagating high-temperature synthesis in an inert gas atmosphere to obtain a silicon carbide powder, wherein
a bulk density of the metal silicon powder and carbon powder after mixing in the mixing step is twice or more a bulk density of the metal silicon powder and carbon powder before said mixing.

2. The method for producing a silicon carbide powder according to claim 1, wherein said subjecting is performed in an electric furnace.

3. The method for producing a silicon carbide powder according to claim 2, wherein in said subjecting, a temperature in the electric furnace is 900 °C to 2050 °C.

4. The method for producing a silicon carbide powder according to claim 1, wherein in said mixing, at least one mixing means selected from the group consisting of a ball mill, a planetary ball mill, a jet mill, and a vibration mill is used.

5. (canceled)

6. The method for producing a silicon carbide powder according to claim 1, further comprising subjecting the obtained silicon carbide powder to a heat treatment in an oxidizing atmosphere.

7. The method for producing a silicon carbide powder according to claim 6, wherein a heat treatment temperature is 600 °C to 1200 °C.

8. (canceled)
